(19) United States
(12) Patent Application Publication
(10) Pub. No.: US 2026/0079200 A1
(43) Pub. Date: Mar. 19, 2026

(54) CIRCUIT DETECTION METHOD AND CIRCUIT DETECTION DEVICE

(71) Applicant: REALTEK SEMICONDUCTOR CORPORATION, Hsinchu (TW)

(72) Inventors: LUNG-CHIN LIU, Hsinchu (TW); Meng-Jung Lee, Hsinchu (TW); Yu-Lan Lo, Hsinchu (TW)

(21) Appl. No.: 19/329,802

(22) Filed: Sep. 16, 2025

(30) Foreign Application Priority Data
Sep. 18, 2024 (TW) 113135353

(51) Int. Cl. G01R 31/28

(52) U.S. Cl. CPC G01R 31/2884

(57) ABSTRACT

A circuit detection method includes: obtaining, from a plurality of transistors of a circuit netlist, at least one main transistor that is electrically connected to at least one high level pin or at least one low level pin; obtaining, from the plurality of transistors, at least one secondary transistor that is electrically connected to the at least one main transistor; determining whether a secondary width-to-length ratio of the at least one secondary transistor is larger than a main width-to-length ratio of the at least one main transistor; and if the secondary width-to-length ratio of the at least one secondary transistor is larger than the main width-to-length ratio of the at least one main transistor, reporting the at least one secondary transistor.

### BACKGROUND OF THE INVENTION

### 1. Field of the Invention

The present disclosure relates to a circuit detection method and a circuit detection device, especially to a circuit detection method and a circuit detection device that can report one or more problematic transistors based on width-to-length ratio.

### 2. Description of Related Art

With the advancement of technology, circuits in electronic products have become increasingly complex. If simulation testing is performed on the circuits, it will take a significant amount of time. In addition, the upper-level circuit and the lower-level circuit in the circuits require different simulation testing approaches, which further increases the difficulty of the simulation testing and the testing time of the simulation testing. If the simulation testing is not performed on the circuits in order to save time, it may fail to detect all deadlocks in the circuits, thereby affecting circuit performance.

### SUMMARY OF THE INVENTION

In some aspects, an object of the present disclosure is to, but not limited to, provides a circuit detection method and a circuit detection device that make an improvement to the prior art.

An embodiment of a circuit detection method of the present disclosure includes: obtaining, from a plurality of transistors of a circuit netlist, at least one main transistor that is electrically connected to at least one high level pin or at least one low level pin; obtaining, from the plurality of transistors, at least one secondary transistor that is electrically connected to the at least one main transistor; determining whether a secondary width-to-length ratio of the at least one secondary transistor is larger than a main width-to-length ratio of the at least one main transistor; and if the secondary width-to-length ratio of the at least one secondary transistor is larger than the main width-to-length ratio of the at least one main transistor, reporting the at least one secondary transistor.

An embodiment of a circuit detection device of the present disclosure includes a memory and a processor. The memory is configured to store a plurality of commands. The processor is configured to read the plurality of commands from the memory to perform following steps: obtaining, from a plurality of transistors of a circuit netlist, at least one main transistor that is electrically connected to at least one high level pin or at least one low level pin; obtaining, from the plurality of transistors, at least one secondary transistor that is electrically connected to the at least one main transistor; determining whether a secondary width-to-length ratio of the at least one secondary transistor is larger than a main width-to-length ratio of the at least one main transistor; and if the secondary width-to-length ratio of the at least one secondary transistor is larger than the main width-to-length ratio of the at least one main transistor, reporting the at least one secondary transistor.

Technical features of some embodiments of the present disclosure make an improvement to the prior art. The circuit detection method and the circuit detection device of the present disclosure can obtain a main transistor electrically connected to a high level pin or a low level pin, and determine whether the width-to-length ratio of the secondary transistor electrically connected to the main transistor is larger than the width-to-length ratio of the main transistor. If the width-to-length ratio of the secondary transistor is larger than the width-to-length ratio of the main transistor, it represents that the driving capability of the main transistor is lower than the driving capability of the secondary transistor, which will result in the main transistor being unable to drive the secondary transistor. The circuit detection method and the circuit detection device of the present disclosure can identify and report such secondary transistors for modification by testing personnel, thereby detecting all deadlocks in the circuit, avoiding performance degradation, and saving simulation time.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows an embodiment of a circuit detection device of the present disclosure.

FIG. 2 shows an embodiment of a flow diagram of a circuit detection method of the present disclosure.

FIG. 3 shows an embodiment of a circuit of the present disclosure.

FIG. 4 shows an embodiment of a circuit of the present disclosure.

### DETAILED DESCRIPTION OF THE PREFERRED EMBODIMENTS

To address the issues in the prior art that circuit simulation testing is time-consuming and unable to detect all deadlocks in the circuit, thereby affecting circuit performance, the present disclosure provides a circuit detection method and a circuit detection device, which will be explained in detail below.

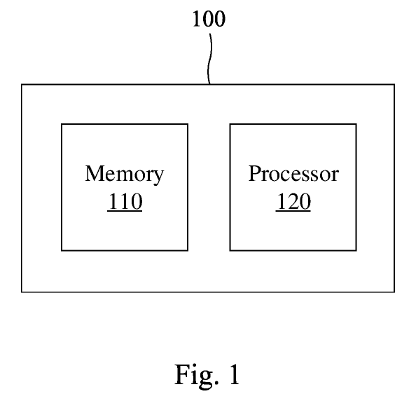

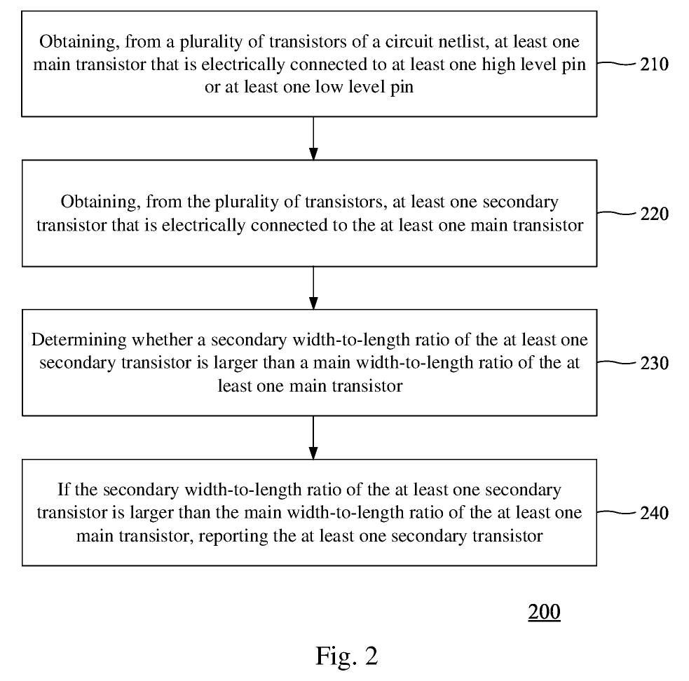

FIG. 1 shows an embodiment of a circuit detection device 100 of the present disclosure. As shown in the figure, the circuit detection device 100 includes a memory 110 and a processor 120. The memory 110 is configured to store a plurality of commands. The processor 120 is configured to read the plurality of commands from the memory 110 to perform corresponding operations. To facilitate understanding of the operation of the circuit detection device 100, please also refer to FIG. 2, which shows an embodiment of a flow diagram of a circuit detection method 200 of the present disclosure.

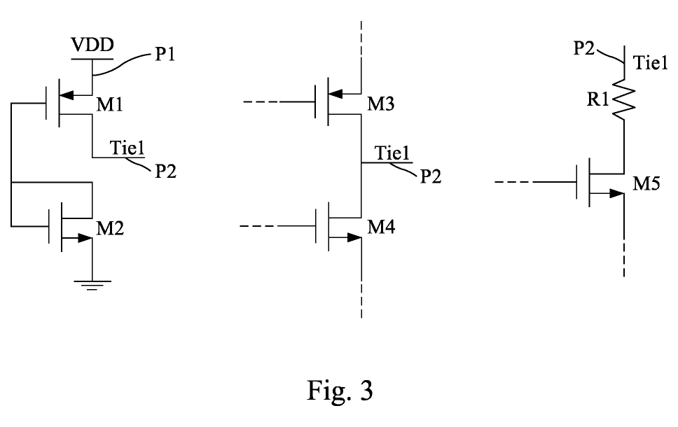

In step 210, obtaining, from a plurality of transistors of a circuit netlist, at least one main transistor that is electrically connected to at least one high level pin or at least one low level pin. For example, referring to FIG. 3, the circuit detection device 100 of the present disclosure may obtain, from a plurality of transistors M1~M5 of a circuit netlist, a main transistor M1 that is electrically connected to a high level pin P1. In some embodiments, the high level pin P1 is electrically connected to a power terminal VDD. In some embodiments, the main transistor M1 is directly electrically connected to the high level pin P1. In some embodiments, the transistors M1, M2 can be a voltage clamp circuit (e.g., Tie Cell). In addition, since the transistor M1 is electrically connected to the power terminal VDD, the voltage clamp circuit formed by the transistors M1, M2 is a high-level voltage clamp circuit (Tie 1/Tie High). In some embodiments, the main transistor M1 is electrically connected to a diode-connected transistor M2.

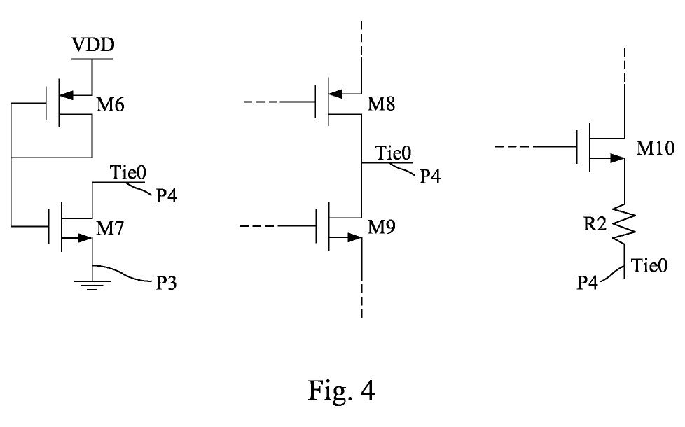

Additionally, referring to FIG. 4, the circuit detection device 100 of the present disclosure may obtain, from a plurality of transistors M6 to M10 of a circuit netlist, a main transistor M7 that is electrically connected to a low level pin P3. In some embodiments, the low level pin P3 is electrically connected to a ground terminal (e.g., ground terminal GND) or a low voltage terminal (e.g., low voltage terminal VSS). In some embodiments, the main transistor M7 is directly electrically connected to the low level pin P3. In some embodiments, the transistors M6, M7 can be a voltage clamp circuit. In addition, since the transistor M7 is electrically connected to a ground terminal or a low voltage terminal, the voltage clamp circuit formed by the transistors M6, M7 is a low-level voltage clamp circuit (Tie 0/Tie Low). In some embodiments, the main transistor M7 is electrically connected to a diode-connected transistor M6. However, the present disclosure is not limited to the above embodiments, which are merely intended to illustratively describe one of the implementations of the present disclosure. In other embodiments, the present disclosure may adopt other suitable circuit structures and quantities of transistors depending on accrual requirements.

In some embodiments, the step 210 further includes the following operations. Referring to FIGS. 3 and 4, the circuit detection device 100 of the present disclosure first obtains a circuit netlist including a plurality of transistors (e.g., transistors M1~M5 or M6~M10). Subsequently, the circuit detection device 100 of the present disclosure obtains a plurality of high level pins (e.g., pin P1) or a plurality of low level pins (e.g., pin P3) from the circuit netlist. Next, the circuit detection device 100 of the present disclosure obtains, from the plurality of transistors (e.g., transistors M1~M5 or M6~M10), a plurality of main transistors (e.g., transistor M1 or M7) that are electrically connected to the plurality of high level pins (e.g., pin P1) or the plurality of low level pins (e.g., pin P3).

In step 220, obtaining, from the plurality of transistors, at least one secondary transistor that is electrically connected to the at least one main transistor. For example, referring to FIG. 3, the secondary transistors M3~M5 are electrically connected to the main transistor M1 via the pin P2. The circuit detection device 100 of the present disclosure may obtain the secondary transistors M3~M5 that are electrically connected to the main transistor M1. Additionally, referring to FIG. 4, the secondary transistors M8~M10 are electrically connected to the main transistor M7 via the pin P4. The circuit detection device 100 of the present disclosure may obtain the secondary transistors M8~M10 that are electrically connected to the main transistor M7.

In some embodiments, referring to FIG. 3, the secondary transistors M3~M4 are directly electrically connected to the main transistor M1, and the secondary transistor M5 is indirectly electrically connected to the main transistor M1 via a resistor R1. Additionally, referring to FIG. 4, the secondary transistors M8~M9 are directly electrically connected to the main transistor M7, and the secondary transistor M10 is indirectly electrically connected to the main transistor M7 via a resistor R2.

In step 230, determining whether a secondary width-to-length ratio of the at least one secondary transistor is larger than a main width-to-length ratio of the at least one main transistor. For example, referring to FIG. 3, the circuit detection device 100 of the present disclosure may determine whether the width-to-length ratio of the secondary transistors M3~M5 is larger than the width-to-length ratio of the main transistor M1. Additionally, referring to FIG. 4, the circuit detection device 100 of the present disclosure may determine whether the width-to-length ratio of the secondary transistors M8~M10 is larger than the width-to-length ratio of the main transistor M7.

In some embodiments, step 230 further includes the following operations. Referring to FIG. 3, the circuit detection device 100 of the present disclosure may determine whether the width-to-length ratio of each of the plurality of secondary transistors (e.g., transistors M3~M5) is larger than the width-to-length ratio of a target transistor (e.g., transistor M1) of the plurality of main transistors. For example, referring to FIG. 3, the circuit detection device 100 of the present disclosure may determine whether the width-to-length ratio of the secondary transistor M3 is larger than the width-to-length ratio of the main transistor M1, the circuit detection device 100 of the present disclosure may determine whether the width-to-length ratio of the secondary transistor M4 is larger than the width-to-length ratio of the main transistor M1, or the circuit detection device 100 of the present disclosure may determine whether the width-to-length ratio of the secondary transistor M5 is larger than the width-to-length ratio of the main transistor M1.

In addition, referring to FIG. 4, the circuit detection device 100 of the present disclosure may determine whether the width-to-length ratio of the secondary transistor M8 is larger than the width-to-length ratio of the main transistor M7, the circuit detection device 100 of the present disclosure may determine whether the width-to-length ratio of the secondary transistor M9 is larger than the width-to-length ratio of the main transistor M7, or the circuit detection device 100 of the present disclosure may determine whether the width-to-length ratio of the secondary transistor M10 is larger than the width-to-length ratio of the main transistor M7.

In step 240, if the secondary width-to-length ratio of the at least one secondary transistor is larger than the main width-to-length ratio of the at least one main transistor, reporting the at least one secondary transistor. For example, referring to FIG. 3, if the width-to-length ratio of the secondary transistor M3 is larger than the width-to-length ratio of the main transistor M1, the secondary transistor M3 is reported. In addition, referring to FIG. 4, if the width-to-length ratio of the secondary transistor M8 is larger than the width-to-length ratio of the main transistor M7, the secondary transistor M8 is reported.

As described above, the circuit detection device 100 and the circuit detection method 200 of the present disclosure can obtain a main transistor (e.g., transistors M1, M7) electrically connected to a high level pin (e.g., pin P1) or a low level pin (e.g., pin P3), and determine whether the width-to-length ratio of a secondary transistor (e.g., transistors M3~M5, M8~M10) electrically connected to the main transistor is larger than the width-to-length ratio of the main transistor (e.g., transistors M1, M7). If the width-to-length ratio of the secondary transistor (e.g., transistors M3~M5, M8~M10) is larger than the width-to-length ratio of the main transistor (e.g., transistors M1, M7), it represents that the driving capability of the main transistor (e.g., transistors M1, M7) is lower than the driving capability of the secondary transistor (e.g., transistors M3~M5, M8~M10), which may result in the main transistor (e.g., transistors M1, M7) failing to drive the secondary transistor (e.g., transistors M3~M5, M8~M10). The circuit detection device 100 and the circuit detection method 200 of the present disclosure can identify and report such secondary transistors (e.g., transistors M3~M5, M8~M10) for modification by testing personnel, thereby detecting all deadlocks in the circuit, avoiding performance degradation, and saving simulation time.

In some embodiments, step 240 further includes the following operations. Referring to FIG. 3, if the width-to-length ratio of the secondary transistor M3 is larger than the width-to-length ratio of the main transistor M1, the secondary transistor M3 is reported; if the width-to-length ratio of the secondary transistor M4 is larger than the width-to-length ratio of the main transistor M1, the secondary transistor M4 is reported; and if the width-to-length ratio of the secondary transistor M5 is larger than the width-to-length ratio of the main transistor M1, the secondary transistor M5 is reported. Furthermore, if the width-to-length ratios of a portion of the secondary transistors (e.g., transistors M3, M4) of the plurality of secondary transistors (e.g., transistors M3~M5) are all larger than the width-to-length ratio of the main transistor M1, the portion of the secondary transistors (e.g., transistors M3, M4) are reported together. The reported secondary transistors may subsequently be reviewed by testing personnel. If it is conformed that the width-to-length ratio of the secondary transistors is larger than the width-to-length ratio of the main transistor M1, the testing personnel may modify the circuit to avoid performance degradation.

In addition, referring to FIG. 4, if the width-to-length ratio of the secondary transistor M8 is larger than the width-to-length ratio of the main transistor M7, the secondary transistor M8 is reported; if the width-to-length ratio of the secondary transistor M9 is larger than the width-to-length ratio of the main transistor M7, the secondary transistor M9 is reported; and if the width-to-length ratio of the secondary transistor M10 is larger than the width-to-length ratio of the main transistor M7, the secondary transistor M10 is reported. Furthermore, if the width-to-length ratios of a portion of the secondary transistors (e.g., transistors M8 and M9) among the plurality of secondary transistors M8~M10 are all larger than the width-to-length ratios of the main transistor M7, the portion of the secondary transistors (e.g., transistors M8 and M9) are reported together. The reported secondary transistors may subsequently be reviewed by an engineer, and if confirmed to have a width-to-length ratio larger than the width-to-length ratio of the main transistor M7, the engineer may modify the circuit to avoid degrading circuit performance.

In some embodiments, the first simulation case (e.g., case 1) of the present disclosure is as follows. The circuit detection device 100 of the present disclosure obtains 89,525 transistors from a circuit netlist, with an extraction time of 19 seconds. The width-to-length ratio of the main transistor is 9.5, and the width-to-length ratio of the secondary transistor is 42. The circuit detection device 100 of the present disclosure determines that the width-to-length ratio of the secondary transistor is larger than the width-to-length ratio of the main transistor, and the number of the foregoing secondary transistors is four. The four secondary transistors are reported. The foregoing secondary transistors are subsequently reviewed by testing personnel, and the four secondary transistors are confirmed to be problematic. In view of the above, the circuit detection device 100 of the present disclosure is capable of identifying problematic secondary transistors, and the circuit is then modified by testing personnel to avoid performance degradation.

Furthermore, the second simulation case (e.g., case 2) of the present disclosure is as follows. The circuit detection device 100 of the present disclosure obtains 23,534 transistors from a circuit netlist, with an extraction time of 6 seconds. The width-to-length ratio of the main transistor is 7.125, and the width-to-length ratio of the secondary transistor is 600. The circuit detection device 100 of the present disclosure determines that the width-to-length ratio of the secondary transistor is larger than the width-to-length ratio of the main transistor, and the number of the foregoing secondary transistors is nine. The nine secondary transistors are reported. The foregoing secondary transistors are subsequently reviewed by testing personnel, and the nine secondary transistors are confirmed to be problematic. In view of the above, the circuit detection device 100 of the present disclosure is capable of identifying problematic secondary transistors, and the circuit is then modified by testing personnel to avoid performance degradation.

It should be noted that the present disclosure is not limited to the embodiments as shown in FIGS. 1 to 4, they are merely examples for illustrating the implements of the present disclosure, and the scope of the present disclosure shall be defined based on the claims as shown below. In view of the foregoing, it is intended that the present disclosure covers modifications and variations to the embodiments of the present disclosure, and modifications and variations to the embodiments of the present disclosure also fall within the scope of the following claims and their equivalents.

In view of the above, the circuit detection device 100 and the circuit detection method 200 of the present disclosure can obtain a main transistor electrically connected to a high level pin or a low level pin, and determine whether the width-to-length ratio of the secondary transistor electrically connected to the main transistor is larger than the width-to-length ratio of the main transistor. If the width-to-length ratio of the secondary transistor is larger than the width-to-length ratio of the main transistor, it represents that the driving capability of the main transistor is lower than the driving capability of the secondary transistor, which will result in the main transistor being unable to drive the secondary transistor. The circuit detection device 100 and the circuit detection method 200 of the present disclosure can identify and report such secondary transistors for modification by testing personnel, thereby detecting all deadlocks in the circuit, avoiding performance degradation, and saving simulation time.

It should be noted that people having ordinary skill in the art can selectively use some or all of the features of any embodiment in this specification or selectively use some or all of the features of multiple embodiments in this specification to implement the present invention as long as such implementation is practicable; in other words, the way to implement the present invention can be flexible based on the present disclosure.

The descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A circuit detection method, comprising:
obtaining, from a plurality of transistors of a circuit netlist, at least one main transistor that is electrically connected to at least one high level pin or at least one low level pin;
obtaining, from the plurality of transistors, at least one secondary transistor that is electrically connected to the at least one main transistor;
determining whether a secondary width-to-length ratio of the at least one secondary transistor is larger than a main width-to-length ratio of the at least one main transistor; and
if the secondary width-to-length ratio of the at least one secondary transistor is larger than the main width-to-length ratio of the at least one main transistor, reporting the at least one secondary transistor.

2. The circuit detection method of claim 1, wherein obtaining, from the plurality of transistors of the circuit netlist, the at least one main transistor that is electrically connected to the at least one high level pin or the at least one low level pin comprises:
obtaining the plurality of transistors of the circuit netlist;
obtaining a plurality of high level pins or a plurality of low level pins of the circuit netlist; and
obtaining, from the plurality of transistors of the circuit netlist, a plurality of main transistors that are electrically connected to the plurality of high level pins or the plurality of low level pins.

3. The circuit detection method of claim 2, wherein obtaining, from the plurality of transistors, the at least one secondary transistor that is electrically connected to the at least one main transistor comprises:
obtaining, from the plurality of transistors, a plurality of secondary transistors that are electrically connected to a target transistor of the plurality of main transistors.

4. The circuit detection method of claim 3, wherein determining whether the secondary width-to-length ratio of the at least one secondary transistor is larger than the main width-to-length ratio of the at least one main transistor comprises:
determining whether the secondary width-to-length ratio of each of the plurality of secondary transistors is larger than the main width-to-length ratio of the target transistor of the plurality of main transistors.

5. The circuit detection method of claim 4, wherein if the secondary width-to-length ratio of the at least one secondary transistor is larger than the main width-to-length ratio of the at least one main transistor, reporting the at least one secondary transistor comprises:
if the secondary width-to-length ratios of a portion of the secondary transistors of the plurality of secondary transistors are larger than the main width-to-length ratio of the target transistor of the plurality of main transistors, report the portion of the secondary transistors.

6. The circuit detection method of claim 1, wherein the high level pin is electrically connected to a power terminal, and the at least one low level pin is electrically connected to a ground terminal or a low voltage terminal.

7. The circuit detection method of claim 1, wherein the at least one main transistor is directly electrically connected to the at least one high level pin or the at least one low level pin.

8. The circuit detection method of claim 1, wherein the at least one main transistor is electrically connected to a diode-connected transistor of the plurality of transistors.

9. The circuit detection method of claim 1, wherein the at least one secondary transistor is directly electrically connected to the at least one main transistor.

10. The circuit detection method of claim 1, wherein the at least one secondary transistor is indirectly electrically connected to the at least one main transistor.

11. A circuit detection device, comprising:
a memory, configured to store a plurality of commands; and
a processor, configured to read the plurality of commands from the memory to perform following steps:
obtaining, from a plurality of transistors of a circuit netlist, at least one main transistor that is electrically connected to at least one high level pin or at least one low level pin;
obtaining, from the plurality of transistors, at least one secondary transistor that is electrically connected to the at least one main transistor;
determining whether a secondary width-to-length ratio of the at least one secondary transistor is larger than a main width-to-length ratio of the at least one main transistor; and
if the secondary width-to-length ratio of the at least one secondary transistor is larger than the main width-to-length ratio of the at least one main transistor, reporting the at least one secondary transistor.

12. The circuit detection device of claim 11, wherein obtaining, from the plurality of transistors of the circuit netlist, the at least one main transistor that is electrically connected to the at least one high level pin or the at least one low level pin which is performed by the processor comprises:
obtaining the plurality of transistors of the circuit netlist;
obtaining a plurality of high level pins or a plurality of low level pins of the circuit netlist; and
obtaining, from the plurality of transistors of the circuit netlist, a plurality of main transistors that are electrically connected to the plurality of high level pins or the plurality of low level pins.

13. The circuit detection device of claim 12, wherein obtaining, from the plurality of transistors, the at least one secondary transistor that is electrically connected to the at least one main transistor which is performed by the processor comprises:
obtaining, from the plurality of transistors, a plurality of secondary transistors that are electrically connected to a target transistor of the plurality of main transistors.

14. The circuit detection device of claim 13, wherein determining whether the secondary width-to-length ratio of the at least one secondary transistor is larger than the main width-to-length ratio of the at least one main transistor which is performed by the processor comprises:
determining whether the secondary width-to-length ratio of each of the plurality of secondary transistors is larger than the main width-to-length ratio of the target transistor of the plurality of main transistors.

15. The circuit detection device of claim 14, wherein if the secondary width-to-length ratio of the at least one secondary transistor is larger than the main width-to-length ratio of the at least one main transistor, reporting the at least one secondary transistor which is performed by the processor comprises:
if the secondary width-to-length ratios of a portion of the secondary transistors of the plurality of secondary transistors are larger than the main width-to-length ratio of the target transistor of the plurality of main transistors, report the portion of the secondary transistors.

16. The circuit detection device of claim 11, wherein the high level pin is electrically connected to a power terminal, and the at least one low level pin is electrically connected to a ground terminal or a low voltage terminal.

17. The circuit detection device of claim 11, wherein the at least one main transistor is directly electrically connected to the at least one high level pin or the at least one low level pin.

18. The circuit detection device of claim 11, wherein the at least one main transistor is electrically connected to a diode-connected transistor of the plurality of transistors.

19. The circuit detection device of claim 11, wherein the at least one secondary transistor is directly electrically connected to the at least one main transistor.

20. The circuit detection device of claim 11, wherein the at least one secondary transistor is indirectly electrically connected to the at least one main transistor.
